(19) United States
(12) Patent Application Publication
(10) Pub. No.: US 2009/0108332 A1
(43) Pub. Date: Apr. 30, 2009

(54) Non-volatile memory device with charge trapping layer and method for fabricating the same

(75) Inventors: Moon Sig Joo, Icheon-si (KR); Ki Seon Park, Yongin-si (KR); Yong Top Kim, Seoul (KR); Jae Young Park, Icheon-si (KR); Ki Hong Lee, Suwon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: Hynix Semiconductor Inc., Icheon-si (KR)

(21) Appl. No.: 12/163,401

(22) Filed: Jun. 27, 2008

(30) Foreign Application Priority Data
Oct. 31, 2007 (KR) 10-2007-0110484

(51) Int. Cl. H01L 29/792; H01L 21/28

(52) U.S. Cl. 257/324; 438/591; 257/E21.18; 257/E29.309

(57) ABSTRACT

Disclosed herein are a non-volatile memory device and a method of manufacturing the same. The non-volatile memory device includes a substrate, a tunneling layer disposed on the substrate, a charge trapping layer disposed on the tunneling layer, a blocking layer disposed on the charge trapping layer, and a control gate electrode disposed on the blocking layer. The blocking layer in contact with the charge trapping layer includes an aluminum nitride layer.

### CROSS-REFERENCE TO RELATED APPLICATION

Priority to Korean patent application No. 10-2007-0110484, filed on Oct. 31, 2007, the disclosure of which is incorporated by reference in its entirety, is claimed.

### BACKGROUND OF THE INVENTION

1. Field of the Disclosure

The invention generally relates to a semiconductor memory device and a method of making the same. More particularly, the invention relates to a non-volatile memory device that includes a charge trapping layer contacting a blocking layer, wherein the portion of the blocking layer contacting the charge trapping layer does not include an oxide material, and a method of making the device.

2. Brief Description of Related Technology

Floating gate structures in non-volatile memory devices do not meet required performance standards because of their limited integrity. Therefore, floating gates have been replaced by non-volatile memory devices with charge trapping layers. Non-volatile memory devices with a charge trapping layer have a structure where a tunneling layer, a charge trapping layer, a blocking layer, and a control gate electrode are sequentially stacked. The non-volatile memory device with the charge trapping layer may have, for example, a silicon-oxide-nitride-oxide-silicon (SONOS) structure or a metal-aluminum oxide-nitride-oxide-silicon (MANOS) structure.

In a non-volatile memory device with a MANOS structure, the control gate electrode is generally formed of metal. The blocking layer is generally formed of aluminum oxide (Al₂O₃) using chemical vapor deposition (CVD) or atomic layer deposition (ALD). The aluminum oxide layer is known to be effective in preventing backward tunneling where charges tunnel from the charge trapping layer to the control gate electrode.

However, an oxidant, such as O₂ gas, O₃ gas, or H₂O gas, used for depositing the aluminum oxide layer may oxidize the upper portion of the silicon nitride charge trapping layer. This forms a silicon oxynitride (SiON) layer between the silicon nitride layer and the aluminum oxide layer. Furthermore, during thermal treatment and the like after formation of the aluminum oxide layer, the silicon oxynitride may grow further because of H₂O or O₂ diffusing through the aluminum oxide layer.

The silicon oxynitride layer between the charge trapping layer of silicon nitride and the blocking layer of aluminum oxide may cause charge loss from the charge trapping layer because it has many shallow trap sites. Accordingly, the data-storing capability of the device may deteriorate.

### SUMMARY OF THE INVENTION

It has now been discovered that a blocking layer made of material other than just an oxide, but having a dielectric constant similar to that of aluminum oxide can desirably be used in the manufacture of a non-volatile memory device and should avoid oxidation of the charge trapping layer. Furthermore, it has now been discovered that a blocking layer of material having a conduction band offset similar to that of aluminum oxide is another characteristic of a desirably effective blocking layer. Aluminum nitride is a material that has a dielectric constant and a conduction band offset similar to that of aluminum oxide.

Accordingly, a non-volatile memory device employing an aluminum nitride blocking layer, and a method of making the same are disclosed herein. In one embodiment, a non-volatile memory device: a substrate; a tunneling layer disposed on the substrate; a charge trapping layer disposed on the tunneling layer; a blocking layer including aluminum nitride, the blocking layer disposed on the charge trapping layer; and a control gate electrode disposed on the blocking layer. In another embodiment, the blocking layer has a structure where an aluminum nitride layer and an aluminum oxide layer are sequentially stacked, the aluminum nitride layer contacting the charge trapping layer.

The disclosed method includes forming the tunneling layer on a substrate; forming the charge trapping layer on the tunneling layer; forming the blocking layer on the charge trapping layer; and forming the control gate electrode on the blocking layer.

Additional features of the invention may become apparent to those skilled in the art from a review of the following detailed description, taken in conjunction with the drawings and the appended claims.

### BRIEF DESCRIPTION OF THE DRAWINGS

For a more complete understanding of the disclosure, reference should be made to the following detailed description and accompanying drawings, wherein:

FIG. 1 illustrates a cross-sectional view of a non-volatile memory device with a charge trapping layer according to one embodiment of the present invention;

FIG. 2 illustrates a cross-sectional view of a non-volatile memory device according to another embodiment of the invention;

FIGS. 3 and 4 illustrate a method of making the non-volatile memory device of FIG. 1; and,

FIGS. 5 and 6 illustrate a method of making the non-volatile memory device of FIG. 2.

While the disclosed device and method are susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DETAILED DESCRIPTION OF SPECIFIC EMBODIMENTS

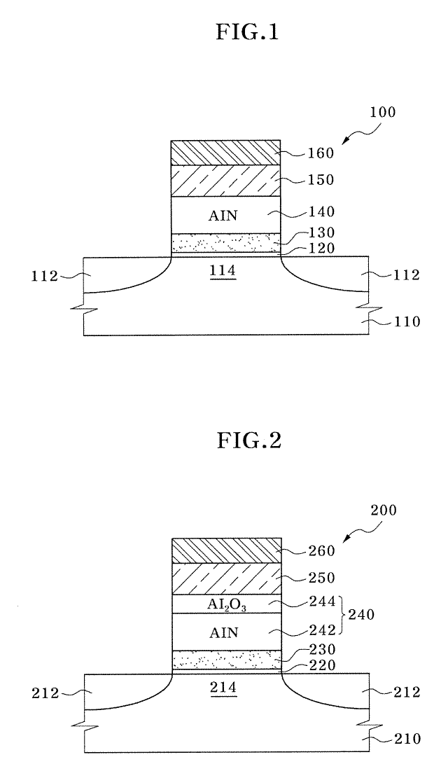

Referring now to the drawings wherein like reference numbers represent the same or similar elements in the various figures, FIG. 1 illustrates a cross-sectional view of a non-volatile memory device 100 that includes a tunneling layer 120, a charge trapping layer 130, a blocking layer 140, a control gate electrode 150, and a low resistance layer 160 sequentially disposed on a substrate 110. A plurality of impurity regions 112, such as source/drain regions, are disposed in an upper portion of the substrate 110, as shown in FIG. 1, for example. A channel region 114 is disposed between the impurity regions 112.

The substrate 110 may be a silicon substrate or a silicon on insulator (SOI) substrate, however, the present invention is not limited thereto. The tunneling layer 120 may be formed of an oxide with a thickness of approximately 20 angstroms (Å) or greater.

The charge trapping layer 130 includes a stoichiometric silicon nitride (Si₃N₄) layer, a silicon-rich silicon nitride (SiₓN_{y}, where the fraction “x/y” is greater than ¾) layer, or a combined structure of both. The charge trapping layer 130 may have a thickness of approximately 40 Å to approximately 100 Å.

As indicated above, it has now been discovered that a blocking layer made of material other than just an oxide, but having a dielectric constant similar to that of aluminum oxide can desirably be used in the manufacture of a non-volatile memory device and should avoid oxidation of the charge trapping layer. Furthermore, it has now been discovered that a blocking layer of material having a conduction band offset (CBO) similar to that of aluminum oxide is another characteristic of a desirably effective blocking layer. Aluminum nitride is a material that has a dielectric constant and a CBO similar to that of aluminum oxide. Specifically, aluminum nitride has a dielectric constant of approximately 8.5, whereas aluminum oxide has a dielectric constant of approximately 9.0. Furthermore, and unlike other metal nitrides, aluminum nitride also has a CBO that is desirably similar to that of aluminum oxide.

Accordingly, in a preferred embodiment, the blocking layer 140 is formed of aluminum nitride (AlN). The blocking layer 140 preferably has a thickness of approximately 100 Å to approximately 300 Å. In addition, the aluminum nitride layer does not contain any oxides, therefore, an oxidant is not required to form the aluminum nitride layer. Therefore, oxidation of the upper portion of the charge trapping layer 130, which generates silicon ovynitride, is prevented.

The control gate electrode 150 may be formed of a metal with a work function greater than approximately 4.5 electron volts (eV), such as tantalum nitride (TaN). The low resistance layer 160 reduces the resistivity of the word line. The low resistance layer 160 may be a combined structure of polysilicon, tungsten nitride (WN), and tungsten silicide (WSi), or a combined structure of tungsten nitride and tungsten (W).

FIG. 2 illustrates a cross-sectional view of a non-volatile memory device with a charge trapping layer according to another embodiment. Referring to FIG. 2, the non-volatile memory device 200 includes a tunneling layer 220, a charge trapping layer 230, a blocking layer 240, a control gate electrode 250, and a low resistance layer 260 disposed on a substrate 210. A plurality of impurity regions 212, such as source/drain regions, are disposed in an upper portion of the substrate 210. A channel region 214 is disposed between the impurity regions 212.

The substrate 110 may be a silicon substrate or a SOI substrate, however, the present invention is not limited thereto. The tunneling layer 220 may be formed of an oxide with a thickness of approximately 20 Å or greater.

The charge trapping layer 230 includes a stoichiometric silicon nitride (Si₃N₄) layer, a silicon-rich silicon nitride (SiₓN_{y}, where the fraction “x/y” is greater than ¾) layer, or a combined structure of both. The charge trapping layer 230 may have a thickness of approximately 40 Å to approximately 100 Å.

The blocking layer 240 preferably has a thickness of approximately 100 Å to approximately 300 Å. The blocking layer 240 shown in FIG. 2 includes a two-layer structure where an aluminum nitride layer 242 and an aluminum oxide layer 244 are sequentially stacked atop the charge trapping layer 230. The aluminum nitride layer 242 is disposed on the charge trapping layer 230 to prevent the oxidation of an upper portion of the charge trapping layer 230, which generates silicon oxynitride. In addition, the aluminum oxide layer 244 has a relatively high energy band gap with the charge trapping layer 230 and is disposed on the aluminum nitride layer 242 to improve the blocking effect further.

The control gate electrode 250 may be formed of a metal with a work function greater than approximately 4.5 eV, such as tantalum nitride. The low resistance layer 260 reduces resistivity of the word line. The low resistance layer 260 may be a combined structure of polysilicon, tungsten nitride, and tungsten silicide, or a combined structure of tungsten nitride and tungsten.

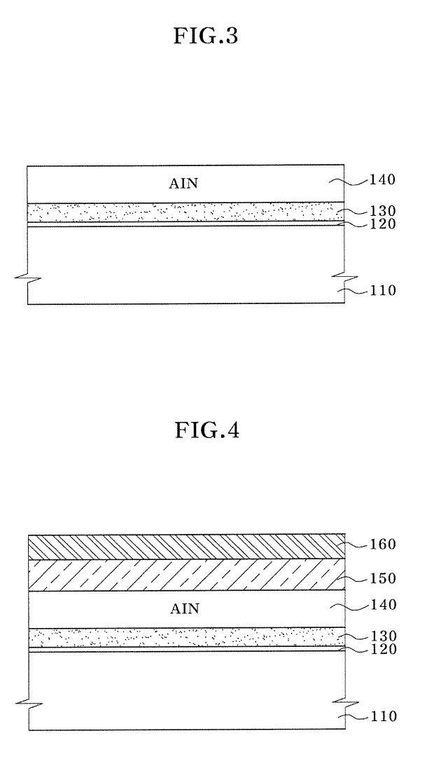

FIGS. 3 and 4 illustrate a method for fabricating the non-volatile memory device of FIG. 1. Referring to FIG. 3, a tunneling layer 120 is formed on a substrate 110. The substrate 110 may be formed of silicon or SOI. The tunneling layer 120 can be formed by radical or thermal oxidation processes generally known by those having ordinary skill in the art. Preferably, however, the tunneling layer 120 is formed by a radical oxidation process. The tunneling layer 120 may be formed of an oxide to a thickness of approximately 20 Å or greater. For example, the oxide may have a thickness of approximately 20 Å to approximately 60 Å.

A charge trapping layer 130 is formed on the tunneling layer 120. The charge trapping layer 130 may be formed of stoichiometric silicon nitride (Si₃N₄), silicon-rich silicon nitride (SIₓN_{y}, where the fraction “x/y” is greater than ¾), or a combined structure of both. The charge trapping layer 130 may have a thickness of approximately 40 Å to approximately 100 Å. The charge trapping layer 130 may be formed using CVD or ALD processes, generally known by those having ordinary skill in the art. Preferably, however, the charge trapping layer 130 is formed by a CVD process.

Thereafter, a blocking layer 140 is formed on the charge trapping layer 130. The blocking layer 140 preferably has a thickness of approximately 100 Å to approximately 300 Å. The blocking layer 140 preferably is formed of aluminum nitride using a sputtering process; although, CVD and ALD processes are also contemplated. In the sputtering process, an aluminum (Al) target is sputtered in a nitrogen (N₂) atmosphere. In CVD and ALD, the reaction gas is ammonia (NH₃) gas. Importantly, no oxidant is needed in any of these processes, therefore, the upper portion of the charge trapping layer 130 is not oxidized. For deposition of the aluminum nitride layer 140, the ratio of aluminum to nitrogen may be approximately 4:1 to approximately 1:4. For example, in one embodiment, the ratio of aluminum to nitrogen is 1:1. After forming the aluminum nitride layer, a rapid thermal processing (RTP) may be performed to densify the layer.

Referring to FIG. 4, a control gate electrode 150 is formed on the blocking layer 140. The control gate electrode 150 may be formed of a metal with a work function greater than approximately 4.5 eV, such as tantalum nitride. The control gate electrode 150 may be formed by CVD, ALD, atomic vapor deposition (AVD), or sputtering processes, generally known by those having ordinary skill in the art. Preferably, however, the control gate electrode 150 is formed by a CVD or an ALD process. Then, a low resistance layer 160 is formed on the control gate electrode 150 to reduce resistivity of the word line. The low resistance layer 160 may have a combined structure of polysilicon, tungsten nitride, and tungsten silicide, or a combined structure of tungsten nitride and tungsten. A typical patterning is performed to form a gate stack, and impurity ions are implanted on the substrate 110 to form the impurity regions 112 shown in FIG. 1.

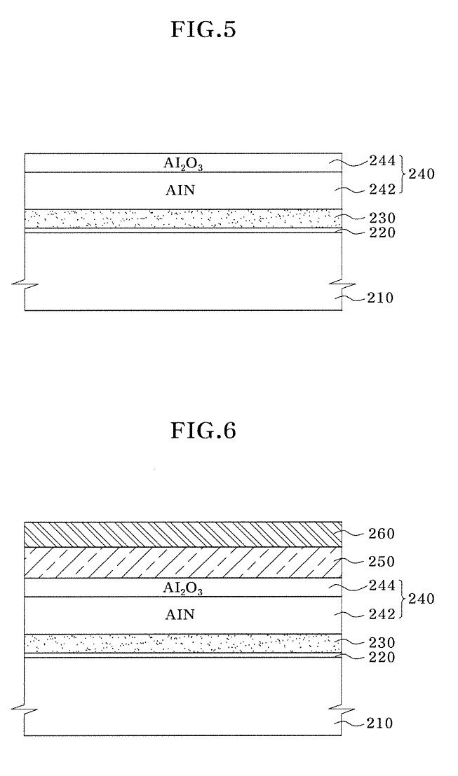

FIGS. 5 and 6 illustrate a method for fabricating the non-volatile memory device of FIG. 2. Referring to FIG. 5, a tunneling layer 220 is formed on the substrate 210. The substrate 210 may be formed, for example, of silicon or silicon on insulator. The tunneling layer 220 may be formed of an oxide to a thickness of approximately 20 Å or greater. For example, the oxide may be approximately 20 Å to approximately 60 Å.

A charge trapping layer 230 is formed on the tunneling layer 220. The charge trapping layer 230 may be formed of stoichiometric silicon nitride (Si₃N₄), silicon-rich silicon nitride (SiₓN_{y}, where the fraction “x/y” is greater than ¾), or a combined structure of both. The charge trapping layer 230 may have a thickness of approximately 40 Å to approximately 100 Å. The charge trapping layer 230 may be formed using CVD or ALD processes generally known by those having ordinary skill in the art. Preferably, however, the charge trapping layer 230 is formed by a CVD process.

Thereafter, a blocking layer 240 is formed on the charge trapping layer 230. The blocking layer 240 preferably has a thickness of approximately 100 Å to approximately 300 Å. The blocking layer 240 has a structure where an aluminum nitride layer 242 and an aluminum oxide layer 244 are sequentially stacked. The aluminum nitride layer 242 preferably is formed using a sputtering process; although, CVD and ALD processes are also contemplated. In CVD and ALD, ammonia gas is the reaction gas. In the sputtering process, an aluminum target is sputtered in a nitrogen atmosphere. No oxidant is needed in any of the processes, therefore, the upper portion of the charge trapping layer 230 is not oxidized. For deposition of the aluminum nitride layer 242, the ratio of aluminum to nitrogen may be approximately 4:1 to approximately 1:4. For example, in one embodiment, the ratio of aluminum to nitrogen is 1:1. After forming the aluminum nitride layer 242, an RTP may be performed to densify the layer. The aluminum oxide layer 244 may be formed using a CVD or an ALD process. Even if an oxidant is used to form the aluminum oxide layer 244, the aluminum nitride layer 242 sufficiently prevents the oxidation of the upper portion of the charge trapping layer 230.

Referring to FIG. 6, a control gate electrode 250 is formed on the blocking layer 240. The control gate electrode 250 may be formed of a metal with a work function greater than approximately 4.5 eV, such as tantalum nitride. The control gate electrode 250 may be formed by CVD, ALD, AVD, or sputtering processes, generally known by those having ordinary skill in the art. Preferably, however, the control gate electrode 250 is formed by a CVD or an ALD process. A low resistance layer 260 on the control gate electrode 250 reduces resistivity of the word line. The low resistance layer 260 has a combined structure of polysilicon, tungsten nitride, and tungsten silicide, or a combined structure of tungsten nitride and tungsten. A typical patterning is performed to form a gate stack, and impurity ions are implanted on the substrate 210 to form the impurity regions 212 in FIG. 2.

The embodiments of the present invention have been described for illustrative purposes. Those skilled in the art will appreciate that various modifications, additions and substitutions are possible, without departing from the spirit and scope of the invention as recited in the following claims.

What is claimed is:

1. A non-volatile memory device comprising:
a substrate;
a tunneling layer disposed on the substrate;
a charge trapping layer disposed on the tunneling layer;
a blocking layer comprising an aluminum nitride layer, the blocking layer disposed on the charge trapping layer; and
a control gate electrode disposed on the blocking layer.

2. The non-volatile memory device of claim 1, wherein the aluminum nitride layer has a composition ratio of aluminum (Al) nitrogen (N) from approximately 4:1 to approximately 1:4.

3. The non-volatile memory device of claim 1 wherein the blocking layer further comprises an aluminum oxide layer, the blocking layer having a structure where the aluminum nitride layer and the aluminum oxide layer are sequentially stacked.

4. A method for forming a non-volatile memory device, the method comprising:
forming a tunneling layer on a substrate;
forming a charge trapping layer on the tunneling layer;
forming a blocking layer comprising an aluminum nitride layer on the charge trapping layer; and
forming a control gate electrode on the blocking layer.

5. The method of claim 4, wherein the blocking layer is formed by a chemical vapor deposition process, an atomic layer deposition process, or a sputtering process.

6. The method of claim 5, wherein the blocking layer is formed by a chemical vapor deposition process or an atomic layer deposition process.

7. The method of claim 6, wherein the chemical vapor deposition process or the atomic-layer deposition process uses ammonia gas as a reaction gas.

8. The method of claim 5, wherein the blocking layer is formed by a sputtering process.

9. The method of claim 8, wherein the sputtering process, comprises sputtering an aluminum target in a nitrogen atmosphere.

10. The method of claim 4, wherein the blocking layer has a composition ratio of aluminum:nitrogen from approximately 4:1 to approximately 1:4.

11. The method of claim 4 wherein the blocking layer further comprises an aluminum oxide layer, the blocking layer having a structure where the aluminum nitride layer and the aluminum oxide layer are sequentially stacked atop the charge trapping layer.
